(19) United States
(12) Patent Application Publication
(10) Pub. No.: US 2009/0251960 A1
(43) Pub. Date: Oct. 8, 2009

(54) HIGH TEMPERATURE MEMORY DEVICE

(75) Inventors: Roger L. Schultz, Aubrey, TX (US); James J. Freeman, Houston, TX (US)

Correspondence Address: KRUEGER ISELIN LLP (1391), P O BOX 1906, CYPRESS, TX, 77410-1906, US

(73) Assignee: Halliburton Energy Services, Inc., Houston, TX (US)

(21) Appl. No.: 12/098,549

(22) Filed: Apr. 7, 2008

(51) Int. Cl. H01L 29/12; G11C 16/04; G11C 11/02; G11C 11/22

(52) U.S. Cl. 365/185.01; 365/145; 365/158; 257/77; 257/E29.068

(57) ABSTRACT

Disclosed herein are various nonvolatile integrated device embodiments suitable for use at high temperatures. In some embodiments, a high temperature nonvolatile integrated device comprises a sapphire or spinel substrate having multiple ferroelectric memory cells disposed upon it. In other embodiments, a high temperature nonvolatile integrated device comprises a silicon on insulator substrate or a large bandgap semiconductor substrate having multiple ferroelectric or magnetic memory cells disposed on it. In yet other embodiments, a high temperature nonvolatile integrated device comprises a sapphire, silicon on insulator, or a large bandgap substrate having programmable read only memory (PROM) cells or electrically erasable PROM (EEPROM) cells disposed on it.

### CROSS-REFERENCE TO RELATED APPLICATIONS

The present application claims priority to the following patent applications:

U.S. Provisional Patent Application 60/520,950, filed Nov. 18, 2003,

U.S. Provisional Patent Application 60/520,992, filed Nov. 18, 2003, and

U.S. Provisional Patent Application 60/523,150, filed Nov. 18, 2003.

The foregoing applications are hereby incorporated by reference.

### STATEMENT REGARDING FEDERALLY SPONSORED RESEARCH OR DEVELOPMENT

Not applicable.

### BACKGROUND

There exist many environments that may be considered hostile to modern electronics. As one example, consider petroleum drilling and production operations, which can require electronics to operate in a borehole miles below the surface. The borehole environment is often hot, with temperatures approaching and exceeding 200 Celsius. At such temperatures, bulk-silicon based memory devices may suffer performance degradation to the point of inoperability.

Memory devices include an array of memory cells and some support circuitry. At high temperatures, bulk-silicon based transistors in the support circuitry suffer from large leakage currents. The leakage currents degrade circuit performance and may even cause permanent damage as the resistive heating from such leakage currents contributes to the problem in a runaway fashion. In the array of memory cells, each memory cell includes one or more elements that store state information in some physical form (e.g., an electrical charge or voltage). In many existing memories, power is consumed to maintain the state information. Such power consumption increases when leakage current increases, thereby causing increased temperatures, increased leakage currents, and increased power consumption in an often-destructive trend. In another, not entirely distinct, group of memories, the state information is maintained as a charge on an electrically insulated conductor. Increased temperatures create thermally excited carriers that may cause the charge to bleed away, thereby destroying the state information.

Given such difficulties with memory device operation at elevated temperatures, it would be desirable to have a memory device that does not suffer from excessive charge bleeding or excessive leakage currents at high temperatures.

### SUMMARY

Accordingly, there is disclosed herein various nonvolatile integrated device embodiments suitable for use at high temperatures. In some embodiments, a high temperature nonvolatile integrated device comprises a sapphire or spinel substrate having multiple ferroelectric memory cells disposed upon it. In other embodiments, a high temperature nonvolatile integrated device comprises a silicon on insulator substrate or a large bandgap semiconductor substrate having multiple ferroelectric or magnetic memory cells disposed on it. In yet other embodiments, a high temperature nonvolatile integrated device comprises a sapphire, silicon on insulator, or a large bandgap substrate having programmable read only memory (PROM) cells or electrically erasable PROM (EEPROM) cells disposed on it.

### BRIEF DESCRIPTION OF THE DRAWINGS

A better understanding of the disclosed embodiments can be obtained when the following detailed description is considered in conjunction with the following drawings, in which:

FIG. 1 shows a schematic for a CMOS inverter;

FIG. 2 shows an illustrative inverter implemented by a silicon on insulator (SOI) process;

FIG. 3 shows an illustrative inverter implemented in a large-bandgap semiconductor substrate;

FIG. 4 shows an illustrative inverter implemented by a silicon on sapphire (SOS) process;

FIG. 5 shows an illustrative inverter implemented by an alternative SOS process;

FIG. 6 shows an illustrative integrated memory architecture;

FIG. 7 shows an illustrative memory having a memory cell array organized into multi-bit words;

FIG. 8 shows a schematic representation of a memory cell for certain memory embodiments;

FIG. 9 shows a schematic representation of a memory cell for certain other memory embodiments;

FIG. 10 shows an illustrative floating gate transistor implemented in a SOS process;

FIG. 11 shows an idealized perspective view of one magnetic random access memory (MRAM) cell embodiment;

FIG. 12 shows an idealized perspective view of a second MRAM cell embodiment;

FIG. 13 shows an illustrative ferroelectric random access memory (FRAM) cell element implemented by an SOS process;

FIG. 14 shows an illustrative memory architecture for a FRAM;

FIG. 15 shows an illustrative memory architecture having memory cells with smaller cells coupled in parallel;

FIG. 16 shows an illustrative memory architecture having memory cells with smaller cells coupled in series;

FIG. 17 shows an illustrative memory architecture having memory cells with an alternative series configuration of smaller cells;

FIG. 18 shows an illustrative memory architecture having memory cells with yet another series configuration of smaller cells;

FIG. 19 shows an illustrative electronics package with focused, intermittent cooling; and

FIG. 20 shows an alternative illustrative electronics package with focused intermittent cooling.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### NOTATION AND NOMENCLATURE

Certain terms are used throughout the following description and claims to refer to particular system components and configurations. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The following discussion concerns various high temperature non-volatile memory embodiments, including high temperature programmable read-only memories (PROMs), high temperature electrically-erasable PROMs (EEPROMs), high temperature magnetic random access memories (MRAMs), and high temperature ferroelectric random access memories (FRAMs). Also discussed are various embodiments of programmable logic devices (PLDs), including field-programmable gate arrays (FPGAs). A number of semiconductor technologies are first described below as a basis for implementing these high temperature devices.

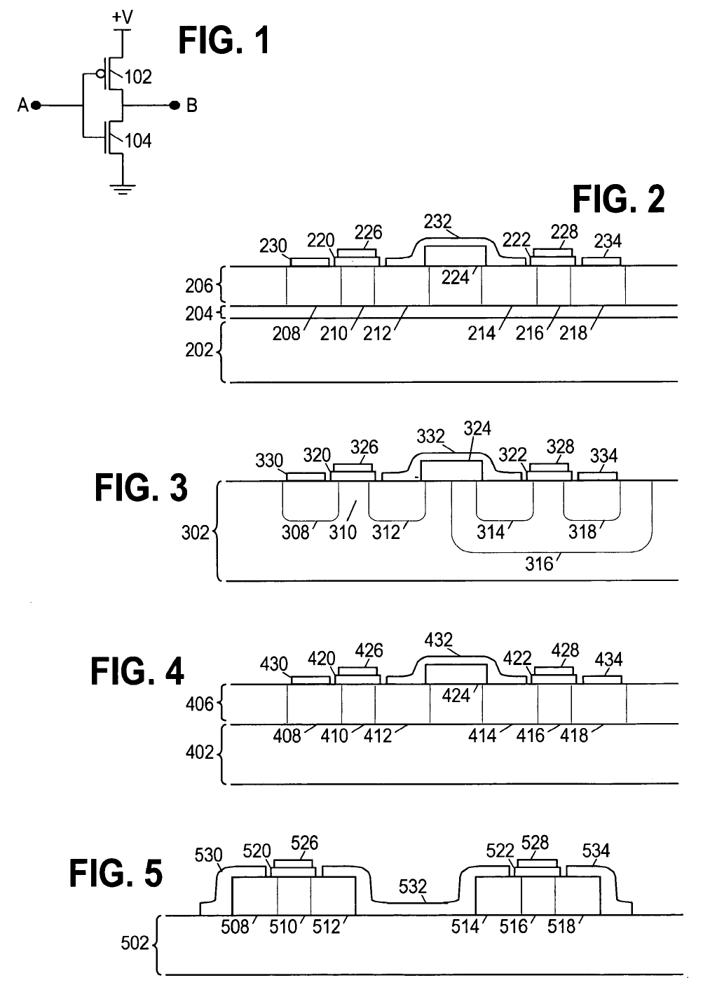

FIG. 1 shows an electrical schematic of an inverter which may be implemented using various semiconductor technologies. The inverter comprises two transistors 102, 104. Transistor 102 is a metal-oxide-semiconductor (MOS) transistor with a p-type active region (PMOS), and transistor 104 is a MOS transistor with an n-type active region (NMOS). Node A is the input node. The inverter drives a digital inverse of the voltage at node A onto node B. This type of transistor configuration may be the basis for a family of digital logic circuits.

FIG. 2 shows an illustrative cross-section of the FIG. 1 inverter constructed using a silicon on insulator (SOI) technology. A silicon wafer 202 serves as a foundation for the integrated circuitry. An insulating layer 204 coats the wafer 202 and separates it from the integrated circuitry. The insulating layer 204 may be silicon dioxide. A thin layer of silicon 206 is disposed on the insulating layer. The silicon layer 206 includes a number of doped regions that provide the active regions for the transistors. Regions 208 and 212 are n⁺-doped regions separated by a p-doped region 210. Regions 214 and 218 are p⁺-doped regions separated by an n-doped region 216.

Regions 210 and 216 are the channel regions, and they are each covered by insulating layers 220 and 222. Insulating layers 220 and 222 may be silicon dioxide, or alternatively may be an insulator with a high dielectric constant. The insulating layers 220 and 222 in turn are topped by conductive gates 226 and 228. The insulating layers 220 and 222 are very thin to allow a significant electric field to penetrate the surface of the channel regions when a small voltage is imposed on the gates. A much thicker insulating layer 224 is provided beneath device interconnects 232 to prevent a significant electric field from penetrating the non-active regions.

When a positive voltage is applied to gate 226, an n-type channel forms in the p-type region 210. The n-type channel provides a low resistance connection between regions 208 and 212. A similar voltage applied to gate 228 eliminates a p-type channel in the n-type region 216, electrically isolating regions 214 and 218. Conversely, when the positive voltage is removed from gate 226, the channel in region 210 disappears, electrically isolating regions 208 and 212. Removing the voltage from gate 228 allows a channel to form in region 216, electrically connecting regions 214 and 218. If electrode 230 is coupled to ground, electrode 234 is coupled to a positive supply voltage, and the gate electrodes are coupled together as an input node, then center electrode 232 is driven to the digital inverse of the voltage on the input node.

Note that this cross-sectional view and the ensuing views are not drawn to scale. The wafer substrate may actually be about 1 mm thick, while the semiconductor layer may (for example) be 10⁻⁸ to 10⁻⁴ m thick. The thickness of the conducting layers may be around 10-100 nm thick, and the gate insulators may be less than 10 nm thick. Due to the thin semiconductor layer used to construct the integrated circuit, the depletion regions around the doped regions have significantly reduced areas. Because leakage currents result from thermally excited carriers in the depletion regions, the significantly smaller depletion regions allow for greatly improved high-temperature performance due to correspondingly reduced leakage currents. More importantly, SOI devices will operate at significantly higher temperatures than bulk silicon devices can achieve.

FIG. 3 shows an illustrative cross section of the FIG. 1 inverter constructed using a large bandgap semiconductor substrate 302. In the illustrative cross section, wafer 302 is doped as a p-type semiconductor. Channel region 310 may then be defined simply by the bounding n⁺-type regions 308 and 312. For the complementary transistor, a substrate region 316 is provided with enough dopant material to change the region to an n-type semiconductor. Within this region, a channel region is defined by its bounding p⁺-type regions 314 and 318. Gate insulators 320 and 322 are provided over the channel regions, and are surmounted by gate electrodes 326 and 328. A thicker insulating layer 324 is used to separate electrical interconnects 332 from the inactive regions of the substrate. As described previously, the desired inverting behavior may be accomplished by coupling electrode 330 to ground, electrode 334 to a positive power supply, and coupling the gate electrodes 326 and 328 together to serve as an input node. The center electrode 332 then carries a digital inverse of the voltage on the input node.

Substrate 302 is a large bandgap semiconductor, meaning that it has a bandgap greater than that of silicon (1.12 eV). Silicon carbide (SiC) is suitable, having a room-temperature bandgap of 2.99 eV. Gallium arsenide (GaAs) may also be suitable, with a bandgap of 1.42 eV. The larger bandgaps significantly reduce the number of thermally excited carriers in the depletion region, thereby reducing undesirable leakage currents and providing acceptable performance at higher temperatures than bulk silicon devices.

FIG. 4 shows an illustrative cross section of the FIG. 1 inverter constructed using a silicon on sapphire (SOS) technology. Substrate 402 is a sapphire or spinel substrate that is electrically nonconductive. A thin silicon layer 406 is disposed on the nonconductive substrate 402. The silicon layer 406 includes a number of doped regions that provide the active regions for the transistors. Regions 408 and 412 are n⁺-doped regions separated by a p-doped region 410. Regions 414 and 418 are p⁺-doped regions separated by an n-doped region 416.

Regions 410 and 416 are the channel regions, and they are each covered by gate insulators 420 and 422. Gate insulators 420 and 422 may be silicon dioxide, or alternatively may be a crystalline insulator with a high dielectric constant. The gate insulators 420 and 422 in turn are topped by conductive gates 426 and 428. The gate insulators 420 and 422 are very thin to allow a significant electric field to penetrate the surface of the channel regions when a small voltage is imposed on the gates. A much thicker insulating layer 424 is provided beneath electrical interconnects 432 to prevent a significant electric field from penetrating the non-active regions. As described previously, the desired inverting behavior may be accomplished by coupling electrode 430 to ground, electrode 434 to a positive power supply, and coupling the gate electrodes 426 and 428 together to serve as an input node. The center electrode 432 then carries a digital inverse of the voltage on the input node.

As with SOI construction, SOS construction provides for performance at high temperatures. The construction of transistors in a thin silicon layer reduces the depletion region size, thereby reducing leakage currents from thermally excited charge carriers in the depletion region.

FIG. 5 shows an illustrative cross section of the FIG. 1 inverter constructed using an alternative SOS process. Substrate 502 is a sapphire or spinel wafer. The transistors are fabricated as islands on the surface of the substrate 502. Channel region 510 comprises p-type silicon sandwiched between n⁺-type ohmic regions 508 and 512. Channel region 516 comprises n-type silicon sandwiched between p⁺-type ohmic regions 514 and 518. Gate insulators 520 and 522 separate gate electrodes 526 and 528 from their respective channel regions. Electrode 530 is coupled to ground, electrode 534 is coupled to a positive supply voltage, and gate electrodes 526 and 528 are coupled together to serve as an input node. Center electrode 532 serves as an output node that carries the digital inverse of the input node voltage.

The island construction further reduces depletion region size, and eliminates stray leakage paths between devices. Devices constructed in this manner can perform at higher temperatures than bulk silicon devices.

The various device constructions described above may be employed in combination with other techniques for increasing the maximum operating temperature. For example, trenches, guard rings, and other structures may be used to eliminate leakage through semiconductor layers 206 or 406, and through substrate 302. (Guard rings are conductive structures around sensitive areas. The structures are held at or near the same potential as the sensitive areas to reduce the electric field gradient, thereby reducing leakage currents).

A number of semiconductor technologies were described above as a basis for implementing high temperature devices. The following discussion concerns various high temperature non-volatile memory embodiments, including high temperature programmable read-only memories (PROMs), high temperature electrically-erasable PROMs (EEPROMs), high temperature magnetic random access memories (MRAMs), and high temperature ferroelectric random access memories (FRAMs).

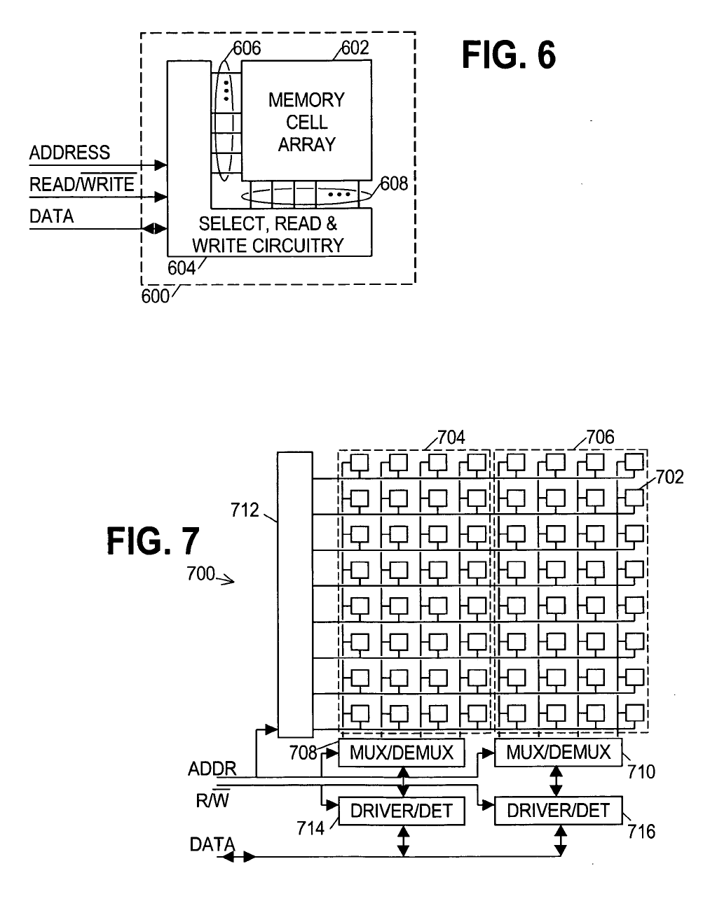

FIG. 6 shows an illustrative integrated memory architecture. Memory 600 comprises a memory cell array 602 and support circuitry 604. The memory cell array 602 is organized in rows and columns. Associated with each row is at least one row line 606, and associated with each column is at least one column line 608. Support circuitry 604 is coupled to the memory cell array via the row lines 606 and column lines 608. In the illustrative architectures described herein, the support circuitry “selects” one row of the memory cell array 602 by asserting a corresponding row line (e.g., driving the voltage on that row line high) while leaving the other row lines de-asserted or floating. The memory cells in the selected row are then available for access via column lines 608. Thus, support circuitry 604 may sense (or “read”) the memory cell states in the selected row, and may provide new memory cell states (or “write”) to the selected row.

The support circuitry 604 receives an address signal that is indicative of the row to be selected for access. The support circuitry further receives a read/write signal that is indicative of the desired type of access to the selected row. For a read access, the support circuitry provides a data signal indicative of the memory cell states sensed in the selected row. For a write access, the support circuitry receives a data signal indicative of the memory cell states to be set in the selected row. A bi-directional data bus may be used to convey the data signals to and from the support circuitry.

In addition to the foregoing functions, support circuitry may implement interface protocols for communicating with other integrated circuit devices. The protocols may include state machine logic for handling sequential operations to perform operations, and may further include level shifter circuitry to convert between internal and external voltage levels. In certain memory architectures, the support circuitry may include charge pumps to generate internal voltages well in excess of the power supply voltage.

FIG. 7 shows a more detailed example of an illustrative integrated memory architecture. Memory 700 includes memory cells 702 organized into an array having two groups of columns 704 and 706. Each column group is coupled to a corresponding multiplexer/demultiplexer 708 and 710. The multiplexers 708 and 710 receive part of the address signal, while the row address decoder 712 receives the remaining part of the address signal. The row address decoder 712 uses its part of the address signal to select a row, while the multiplexers 708 and 710 use their part of the address signal to couple a selected column line to respective driver/detector modules 714 and 716. The driver/detector modules 714 and 716 perform read or write operations in accordance with the state of the read/write signal. When the read/write signal is asserted, the driver/detector modules sense the state of the memory cells at the selected row and columns, and drive the sensed state on the data signal bus. Conversely, when the read/write signal is de-asserted, the driver/detector modules set the state of the memory cells at the selected row and columns in accordance with the signal on the data bus.

Note that memory cells 702 are arranged in a simple rectangular grid of rows and columns. Each memory cell stores one bit of information, though multi-bit cells exist and may also be used. The relationship between the physical array and the logical arrangement of bits into words is determined by the way the address signal is partitioned. The three most significant bits of the address may be used to select one of the eight rows in the illustrated embodiment. The next two bits of the address signal may be used to select one of the four columns associated with each multiplexer. Since only two column groups are provided, each address location contains only two bits (one from each multiplexer). Thus the illustrated embodiment is organized into 32 two-bit words. A practical memory may include over 64 million 32-bit words.

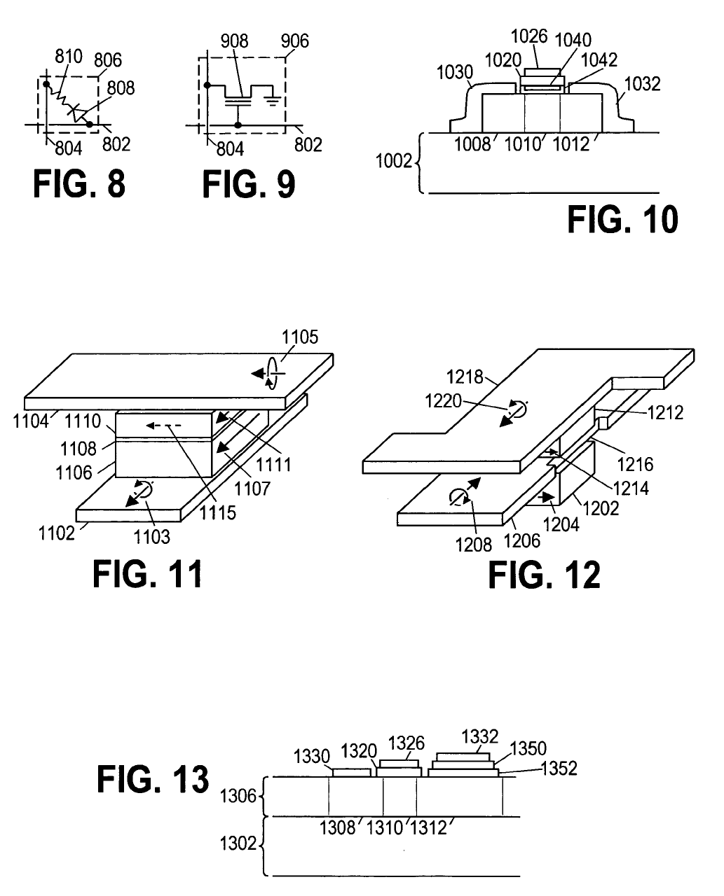

FIG. 8 shows an illustrative memory cell schematic which may represent a PROM cell. A memory cell 806 is provided at each intersection of a row line 802 with a column line 804. Each memory cell 806 includes a diode 808 and a fuse (or anti-fuse) element 810 coupled in series between the row line and the column line. Once programmed, element 810 represents a zero bit value with a high resistance and a one bit value with a low resistance (or vice versa). When the row line 802 is asserted, the current flowing on bit line 804 will reflect the stored bit value. The initial resistance state of element 810 depends on whether fuse (low resistance) or anti-fuse (high resistance) technology is used.

In fuse technology, a thin conductive line is initially provided. The resistance state of selected bits is then changed by driving a large current through the fuse, causing it to heat and change phase to either a liquid or a gas. The mobile phase then separates from the leads, leaving an open circuit. In anti-fuse technology, an amorphous material (e.g., doped silicon) is initially provided. The amorphous material naturally has a high resistance due to the many grain boundaries that inhibit charge conduction. The resistance state of selected memory cells is then changed by driving a large current through the anti-fuse, causing the amorphous material to heat and melt. As the material cools, it crystallizes into a low resistance state with a minimal number of grain boundaries.

Diode 808 allows current to flow to the column lines, but prevents current from leaving the column lines to flow along the row lines. This selectivity is important to prevent currents on the bit lines from bleeding through non-selected row lines and non-selected memory cells to other bit lines. Such bleeding prevents reliable detection of the memory cell states. Accordingly, diode leakage currents will inhibit high temperature performance of the PROM. Operation at high temperatures can be enabled or enhanced though use of SOI processes, SOS processes, and large-bandgap substrates, where leakage currents in the memory cell array and the support circuitry will be significantly reduced.

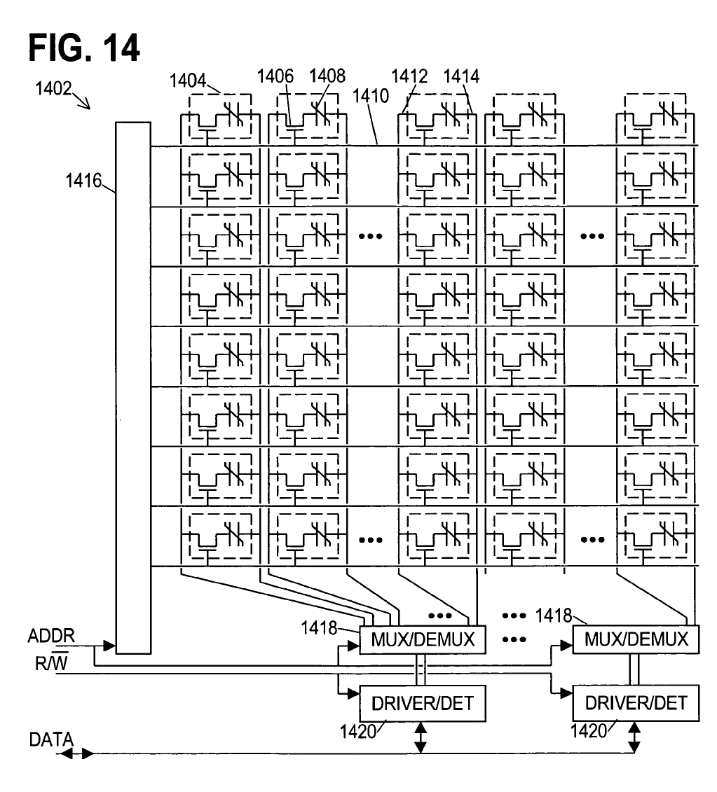

FIG. 9 shows an illustrative memory cell schematic for an EEPROM. Memory cell 906 includes a field effect transistor (FET) 908 having a floating gate between the gate electrode and the channel. The gate electrode is coupled to row line 802, while the channel is coupled between a column line 804 and ground or between a pair of column lines. (A memory architecture with paired column lines is discussed with respect to FIG. 14 below.) When row line 802 is asserted, the FET channel becomes conductive or not, depending on the floating gate's charge. A negative charge on the floating gate inhibits the formation of a conductive channel at a gate electrode voltage where a neutral or positive charge on the gate would allow or enhance the formation of a conductive channel. A driver/detector circuit coupled to column line 714 can apply a voltage to the column line and measure the resulting current flow to determine the charge state on the floating gate. When the row line is not asserted, the conductive channel disappears.

At elevated temperatures, leakage currents caused by thermally excited electrons make detection of the selected memory cell's charge state more difficult, both because a selected transistor in a “non-conductive” state looks conductive in the presence of sufficient leakage, and because unselected transistors with significant leakage currents fail to isolate the column line sufficiently for accurate measurement of the selected transistor. Operation at high temperatures can be enabled or enhanced though use of SOI processes, SOS processes, and large-bandgap substrates, where leakage currents in the memory cell array and the support circuitry will be significantly reduced.

FIG. 10 shows an illustrative example of a floating gate transistor implemented with an SOS process. A sapphire or spinel substrate 1002 supports a silicon island having a p-type region 1010 between two n⁺-type regions 1008 and 1012. Electrodes 1030 and 1032 are ohmically coupled to the n⁺-type regions 1008 and 1012, respectively. The channel region 1010 is topped by a gate insulator 1020 and a gate electrode 1026. Between the channel region 1010 and the gate insulator is a floating gate 1040 which is enclosed by a floating gate insulator 1042. Though surrounded by insulating material, floating gate 1040 can nevertheless be charged and discharged by applying an elevated voltage of the desired polarity to the gate electrode 1026 (a positive voltage if a negative charge is desired on the floating gate, or a negative voltage if a neutral or positive charge is desired on the floating gate). To charge the floating gate via a quantum-tunneling mechanism, electrodes 1030 and 1032 are simply grounded. To charge the floating gate via a hot-electron injection mechanism, an elevated voltage difference is applied between electrodes 1030 and 1032. The elevated voltages described above may be between 5 and 25 times the supply voltage for the memory. The elevated voltages may be created through the use of one or more charge pumps in the support circuitry.

EEPROMs are non-volatile devices, as the floating gates can retain their charges for well in excess of 10 years, regardless of whether power is supplied or not. However, the floating gates requires a relatively lengthy time to charge or discharge, so EEPROM programming operations are relatively slow. Flash memory is a form of EEPROM that allows multiple memory locations to be erased or written at the same time, thereby significantly reducing the average programming time.

Returning to FIG. 8, other resistance elements 810 may be used besides fuses and anti-fuses. In an MRAM, the memory cells include a magnetic tunnel junction (MTJ) or a giant magnetoresistive effect (GMR) element. Such elements offer non-volatility with fast and easy programmability, and do not suffer from depletion region-induced leakage currents.

FIG. 11 shows an idealized MTJ. The MTJ may be formed by placing a thin nonconductive layer 1108 between an electrically conductive hard magnetic layer 1110 and an electrically conductive soft magnetic layer 1106. When a voltage is established between the magnetic layers 1106 and 1110, current carriers “tunnel” through the nonconductive layer 1108. Accordingly, the MTJ structure electrically resembles a resistor. Importantly, the MTJ resistance may be adjusted. When the orientations of the magnetic layers 1106 and 1110 are aligned (parallel) as shown by arrows 1107 and 1111, the resistance is lower than when the orientations are opposed (anti-parallel).

With respect to magnetic materials, the terms “hard” and “soft” connote relatively high and low magnetic coercivities, respectively. A soft magnetic material can be oriented by a weaker magnetic field than can a hard magnetic material. Thus, soft magnetic layer 1110 can be re-oriented without altering the orientation of hard magnetic layer 1106, by simply not allowing the magnetic field to exceed the critical level required for re-orienting the hard magnetic layer.

Another factor that determines the orientation of the magnetic layers is the “easy axis.” Each of the layers may have an axis of preferential orientation along which less of a magnetic field is required to orient the layer, and along which the persistent magnetization of the layer will point (e.g., arrows 1107, 1111). Such an axis may be established by the geometry of the layer and/or by a crystalline orientation of the layer and/or by providing an anti-ferromagnetic layer for exchange biasing. Axes perpendicular to the easy axis are “hard” axes, and may require much higher fields to establish a persistent orientation. In some cases, magnetization along these axes may not be stable.

Arrow 1115 shows a field along a hard axis of the soft magnetic layer 1110. Such a field may be established by passing a current along conductor 1102 as shown by arrows 1103. Current flowing in conductor 1102 creates a circular magnetic field around the conductor in accordance with the “right hand rule.” A current flowing in conductor 1102 may make soft magnetic layer 1110 more susceptible to re-orientation by a magnetic field along its easy axis. Such a field may be provided by a current flowing through conductor 1104 as shown by arrows 1105. Current flowing in the direction shown may orient the soft magnetic layer 1110 as shown by arrow 1111. A current flowing in the opposite direction through conductor 1104 while current flows in conductor 1102 may orient the soft magnetic layer in the direction opposite arrow 1111. Thus currents flowing through a row line 1102 and column line 1104 may store information by appropriately orienting a magnetic layer at the intersection of the row and column lines.

Conductors 1102 and 1104 may be in electrical contact through the MTJ. A parallel orientation of layers in the MTJ may be detected as a (relatively) low resistance between conductors 1102 and 1104, while an anti-parallel orientation may be detected as a (relatively) high resistance between these conductors. If position-dependent variation of memory cell characteristics make it difficult to determine when a measured resistance value is high or low, so-called “destructive read” techniques may be employed. In a destructive read, a measurement of the memory cell's existing state is first made. Then a known state is written to the memory cell, and a second measurement is made. If the measurements match, then the pre-existing state matches the known state. Conversely, if the measurements differ significantly, the pre-existing state is the inverse of the known state. In this latter case, the pre-existing state has been destroyed, and a subsequent write operation is required to re-instate the original state.

FIG. 12 shows an idealized GMR element for as MRAM cell. Unlike an MTJ, the present example includes a conductive layer 1216 sandwiched between a hard magnetic layer 1202 and a soft magnetic layer 1212. Current flowing through conductor 1208 (and consequently though layer 1216) experiences a resistance that depends on the relative magnetic orientations of layers 1202 and 1212. The resistance of the magnetic memory cell comprising layers 1202, 1216, and 1212 may be low when the orientations of layers 1202 and 1212 are aligned (as shown by arrows 1204 and 1214). Conversely, when the orientations the layers are opposed, the resistance of the magnetic memory cell may be high.

The easy axes of the magnetic layers may be transverse to the axis of conductors 1206 and 1218. The orientation of soft layer 1212 may be set in the direction shown by arrow 1214 by passing currents through conductors 1206 and 1218 in the directions shown by arrows 1208 and 1220, respectively. (Conductor 1218 may be electrically isolated from the memory cell.) The magnetic fields around conductors 1206 and 1218 may combine to provide a magnetic field strength sufficient to re-orient soft layer 1212, where the fields individually would be insufficient to do so. The orientation of layer 1212 may be set in a direction opposite arrow 1214 by reversing the currents in both conductors.

FIG. 13 shows an illustrative physical cross-section for a FRAM memory cell implemented using an SOS process. A transistor is created out of n⁺, p, and n⁺ doped regions 1308, 1310, and 1312, respectively, in a layer of silicon 1306 on a sapphire substrate 1302. When a voltage is applied to gate electrode 1326, a conductive channel forms in active region 1310 underneath the gate insulator 1320. The conductive channel electrically couples terminal electrode 1330 to intermediate electrode 1352. A ferroelectric layer 1350 separates another terminal electrode 1332 from intermediate electrode 1352.

The structure formed by electrode 1332, ferroelectric layer 1350, and electrode 1352, electrically behaves much like a capacitor, with the following notable difference. When an electric field is applied to the ferroelectric layer, a “charge spike” will occur if the polarity is opposite the polarity of a previously-applied electric field. This difference allows the structure to be used as a bit memory. The polarity of an applied electric field “sets” the ferroelectric material to one of two possible states. The state can be later determined by the presence or absence of a charge spike when a subsequent electric field is applied. The read operation is destructive, so a re-write may be used to reset the state of the ferroelectric material.

FIG. 14 shows an architectural schematic of an illustrative high-temperature ferroelectric memory 1402 based on the memory cell implementation of FIG. 13. Memory 1402 includes an array of ferroelectric memory cells 1404 arranged in columns and rows. Each ferroelectric memory cell 1404 includes an access transistor 1406 and a ferroelectric memory element 1408. The gate of each access transistor 1406 is coupled to one of multiple row lines 1410. The terminal electrodes of the ferroelectric memory cell are coupled to one of multiple pairs of column lines 1412, 1414. A given ferroelectric memory cell may be accessed (read from or written to) by applying a voltage between the pair of column lines to which the cell is connected, and asserting the corresponding row line. Multiple memory cells from a given row may be accessed simultaneously.

Ferroelectric memory 1402 receives an address signal ADDR, a read/write control signal, and a bidirectional data bus. A column decoder 1416 receives a portion of a memory address ADDR and asserts a corresponding row line. Ferroelectric memory 1402 further includes a set of column line pair multiplexers/demultiplexers (MUX/DEMUX) 1418. Each MUX/DEMUX 1418 receives the remaining portion of the memory address ADDR and couples the corresponding column line pair to a Driver/Detector circuit 1420. For write operations, the driver/detector circuits 1420 drive a voltage between the column line pair with a polarity that indicates the received data bit. For read operations, the driver/detector circuits 1420 drive a predetermined voltage between the column line pair and measure the presence or absence of a charge spike. The presence or absence is decoded as a one or zero (or vice versa), and the detected data is provided on the data bus. If a charge spike is detected, the Driver/Detector circuit 1420 drives an opposite polarity across the column line pair to reset the ferroelectric memory element to its original state.

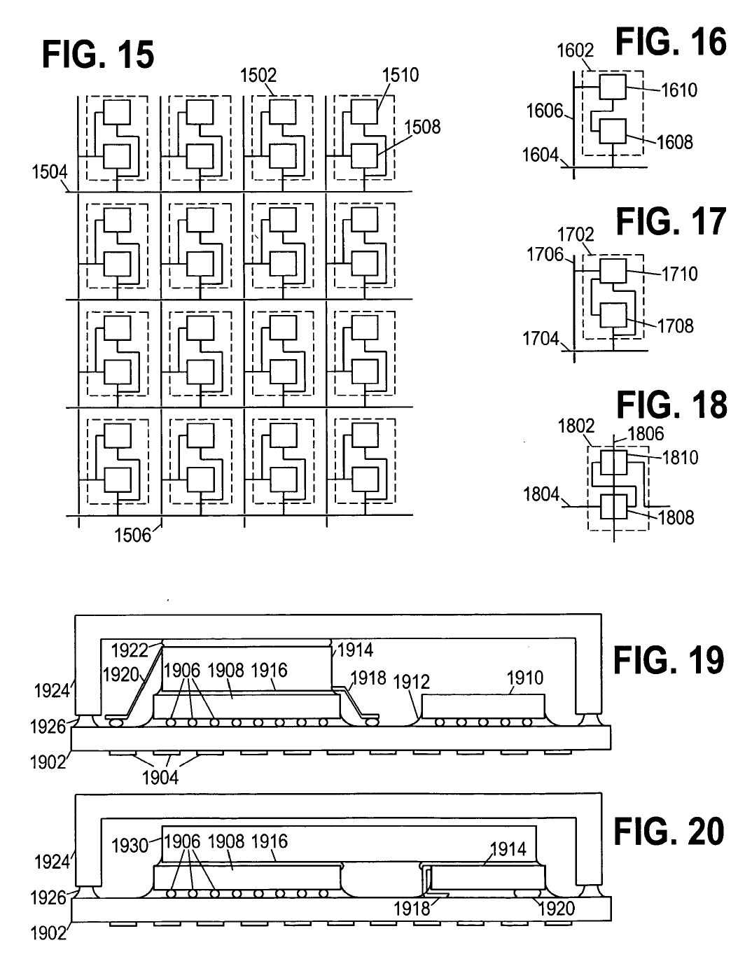

A number of nonvolatile memory cell architectures have now been described. Each of these architectures may be implemented using SOI, SOS, or large-bandgap semiconductor technology. Such construction of the memory arrays and support circuitry may allow the memory to operate at higher temperatures than would be possible with elements implemented in bulk silicon technology. Another technique for enhancing performance in adverse conditions is illustrated in FIGS. 15-17.

FIG. 15 illustrates a technique for enhancing memory array performance by coupling multiple memory cells in parallel at each intersection between a row line and a column line. Thus the array includes composite memory cells 1502 coupled to row lines 1504 and column lines 1506. Each composite cell 1502 includes multiple component memory cells 1508 and 1510 coupled in parallel. In an alternative embodiment, multiple row lines may be asserted together to achieve a similar parallel coupling configuration. Such parallel configurations enhance sensitivity to states stored in FRAM cells without requiring a circuit redesign to provide a larger capacitor geometry. The use of existing cell libraries allows faster device production and enhanced reliability at less cost. Smaller cells also have less stringent surface planarity requirements than do larger cells.

FIG. 16 illustrates a composite memory cell 1602 coupled to a row line 1604 and a column line 1606. Composite memory cell 1602 includes multiple component memory cells 1608 and 1610 coupled in series. In the series configuration illustrated, the column line output of cell 1608 is coupled to the row line input of cell 1610. This series configuration may provide for enhanced sensitivity in MTJ-based MRAM cells.

FIG. 17 illustrates a composite memory cell 1702 coupled to a row line 1704 and a column line 1706. Composite memory cell 1702 includes multiple component memory cells 1708 and 1710 coupled in series. In the series configuration illustrated, the column line output of cell 1708 is coupled to an internal node in memory cell 1710, while both row line inputs are coupled to row line 1704. This series configuration may provide for enhanced sensitivity in EEPROM cells.

In GMR MRAM cells, the column lines and row lines run in series with the magnetoresistive elements. FIG. 18 shows a composite memory cell 1802 at an intersection between row line 1804 and a column line 1806. The composite cell includes component cells 1808 and 1810 coupled in series to enhance detection sensitivity.

The above-described memory architectures are nonvolatile and provide relatively fast read accesses. Nonvolatile memory cells may be employed in other devices to provide a nonvolatile configuration of such devices. For example, reconfigurable logic such as PLDs and FPGAs may employ one or more of the foregoing architectures and may be implemented with a semiconductor process that allows operation at elevated temperatures. Alternatively, a general purpose (high temperature) processor may be coupled to a nonvolatile memory to operate in accordance with program instructions and data stored in the nonvolatile memory. Otherwise volatile configurable devices may similarly be coupled to a nonvolatile memory to retrieve configuration information stored therein whenever power is restored. Examples of such devices include programmable gain amplifiers, configurable analog-to-digital or digital-to-analog converters, latching relays, “sticky” switches that remember their positions after power loss, and circuits needing factory calibration or periodic calibration in the field, such as temperature compensated thermometers, voltage references, digital trimpots, and configurable ASICs.

The memories described herein operate at temperatures greater than bulk silicon integrated memories. Accordingly, these memories may be particularly suitable for operation in high temperature environments such as deep boreholes, jet engines, internal combustion engines, automotive environments, and power generation environments.

Many integrated circuits are subject to performance degradation or failure at moderately elevated temperatures, while other integrated circuits may continue to perform adequately at such temperatures. In various circuits that may be desirable for long-term installation at moderately elevated temperatures, continuous operation is not necessary. Rather, certain portions of a circuit may need to be accessed only briefly and at infrequent intervals, e.g., nonvolatile program memory may only need to be accessed at power-on and reset events. Voltage references may only be needed at infrequent calibration events. In such circuits, refrigeration efforts may be localized to just that portion of the circuit that requires cooling. Further, the refrigeration may be performed only when the operation of the temperature-sensitive circuits is needed. In such circuits, refrigeration operations may be performed directly on the die or package containing the temperature-sensitive circuitry, greatly reducing the thermal mass that needs to be cooled. Further, since the refrigeration operations may be brief and infrequent, the refrigeration system may be small, and the heat sink may be reduced in size or eliminated. In this manner, the size and power requirements for electronics cooling may be drastically reduced. Thus pinpoint refrigeration may be an efficient and desirable way to enable or improve device performance in high temperature environments.

FIG. 19 shows an illustrative multi-chip module (MCM) having a substrate 1902 with pads 1904 for external electrical connections. Electrical paths and pads may also be provided for internal connections on the other side of substrate 1902. In FIG. 19, an integrated circuit die 1908 is shown in a “flip chip” configuration. In this configuration, solder balls 1906 are attached to the active surface of the die 1908, and these balls are positioned against mating balls or pads on substrate 1902. The solder balls are partially melted, forming physical, electrically conductive connections. Other dies 1910 may be similarly mounted. A nonconductive adhesive material 1912 may be introduced into the gap between the dies 1908, 1912 and the substrate 1902 to reinforce the physical attachment. Other MCM configurations such as wire bonding may also be used.

In the MCM of FIG. 19, a Peltier cooler 1914 is mounted on the inactive (“back”) surface of die 1908 with a thermally conductive adhesive 1916. A Peltier cooler is comprises a multi-layer sandwich of interleaved metal layers. As current flows from layer to layer, heat is transported from one surface of the cooler to the opposite surface. Electrode 1918 is attached to the cooled (bottom) surface, and electrode 1920 is attached to the heated (top) surface. These electrodes may be bonded to substrate 1902.

Depending on the various parameters for cooling the electronics and the performance of the cooler, a dedicated heat sink may be unnecessary. In the MCM of FIG. 19, a thermally conductive and deformable material 1922 thermally couples the top surface of the Peltier cooler 1914 to the package cap 1924, which serves a dual purpose as packaging and heat sink. An adhesive bond 1926 attaches cap 1924 to substrate 1902 and seals the package. In one embodiment, the substrate 1902 comprises a ceramic material with patterned metal layers for interconnects. The cap 1924 may be a ceramic, plastic, or metal material.

FIG. 19 shows a variant MCM configuration in which the Peltier cooler 1914 is mounted directly on substrate 1902. The Peltier cooler 1914 cools die 1908 indirectly via a thermal conductor 1930 which is bonded to both the cooler 1914 and die 1908 with thermally conductive adhesive.

Die 1908 may include a Flash memory and a voltage reference. Flash memory can generally retain information at temperatures above the point where the read and write circuitry fails. Upon needing to access the Flash memory to retrieve or store data, a controller may energize the Peltier cooler and pause for a predetermined time interval to allow the memory to cool to an operating temperature range. Once the interval ends, the controller may perform the needed memory accesses and de-energize the cooler. A volatile memory may be used to buffer data traveling to and from the Flash memory, thereby reducing the frequency of accesses to the nonvolatile memory.

In a similar fashion, a controller may energize the Peltier cooler and pause for a predetermined cooling interval before performing a calibration operation with a voltage reference. The accuracy of the voltage reference may be increased by limiting the temperature range in which it is employed.

Numerous variations and modifications will become apparent to those skilled in the art once the above disclosure is fully appreciated. For example, the disclosed invention embodiments may be applied in elevated temperature environments unrelated to wells. For example, the disclosed embodiments may be employed for engine monitoring, heat-driven power generation, materials processing, and oven controls. It is intended that the following claims be interpreted to embrace all such variations and modifications.

1.-8. (canceled)

9. A high temperature nonvolatile integrated device, comprising:
a silicon carbide (SiC) substrate; and
a plurality of ferroelectric memory cells disposed on the substrate.

10. The device of claim 9, wherein the plurality of ferroelectric cells are coupled to form a memory cell array, and wherein the device further comprises support circuitry disposed on the substrate to selectively access cells in the memory array to read and store data.

11. The device of claim 10, wherein the support circuitry includes:
a row decoder to assert, in response to an address value, a corresponding row line; and
a driver/detector module to apply an electric field across a ferroelectric memory element, said ferroelectric memory element made accessible by the assertion of a row line.

12.-19. (canceled)

20. A high temperature nonvolatile integrated device that comprises:
a silicon carbide (SiC) substrate; and
a plurality of magnetic memory cells disposed on the substrate.

21. The device of claim 20, wherein the plurality of magnetic memory cells are coupled to form a random access memory cell array, and wherein the device further comprises support circuitry disposed on the substrate to selectively access cells in the memory array to read and store data.

22. The device of claim 21, wherein the support circuitry includes:
a row decoder to assert, in response to an address value, a corresponding row line; and
a driver/detector module to apply an electric field across a magnetic memory element made accessible by the assertion of a row line.

23.-24. (canceled)

25. The device of claim 20, wherein each magnetic memory cell includes a magnetic tunnel junction (MTJ).

26. The device of claim 20, wherein each magnetic memory cell includes a giant magnetoresistive effect (GMR) element.

27. The device of claim 20, further comprising silicon carbide electronic circuits for operating the plurality of magnetic memory cells, the silicon carbide electronic circuits disposed on the silicon carbide substrate.

28.-37. (canceled)

38. A high temperature electrically erasable and programmable memory that comprises:
a silicon carbide (SiC) substrate; and
a plurality of memory cells disposed on the substrate, each memory cell including a floating gate transistor.

39. The memory of claim 38, wherein the plurality of memory cells are coupled to form a memory cell array, and wherein the device further comprises support circuitry disposed on the substrate to selectively access cells in the memory array to read and store data.

40. The memory of claim 39, wherein the support circuitry includes:
a row decoder to assert, in response to an address value, a corresponding row line; and
a driver/detector module to apply an electric field across a memory element made accessible by the assertion of a row line.

41.-42. (canceled)

43. The memory of claim 39, wherein the device is configured to erase multiple rows of memory cells concurrently.

44. A high temperature electrically erasable and programmable read only memory (EEPROM), comprising:
a silicon carbide substrate;
a plurality of memory cells disposed on the silicon carbide substrate;
a silicon carbide charge pump circuit disposed on the silicon carbide substrate; and
electronic circuits for operating the plurality of memory cells, the silicon carbide electronic circuits disposed on the silicon carbide substrate.

45. The memory of claim 44, wherein the memory is configured as a Flash memory.

46. The memory of claim 44, wherein the plurality of memory cells are coupled in parallel to form a composite memory cell.

47. The memory of claim 44, wherein the plurality of memory cells are coupled in series to form a composite memory cell.

48.-55. (canceled)

56. A high temperature nonvolatile integrated device, comprising:
a silicon carbide (SiC) substrate; and
a plurality of memory cells disposed on the substrate, each memory cell including a fuse or antifuse element.

57. The device of claim 56, wherein the plurality of memory cells are coupled to form a memory cell array, and wherein the device further comprises support circuitry disposed on the substrate to selectively access cells in the memory array to read data.

58. The device of claim 57, wherein the support circuitry includes:
a row decoder to assert, in response to an address value, a corresponding row line; and
a detector module to apply an electric field across a fuse or antifuse element made accessible by the assertion of a row line.

59.-66. (canceled)
